(19) United States
(12) Patent Application Publication
(10) Pub. No.: US 2026/0206179 A1
(43) Pub. Date: Jul. 16, 2026

(54) MULTI-HEAT SOURCE LIQUID COOLING DEVICE

(71) Applicant: SHENZHEN APALTEK CO., LTD., Shenzhen (CN)

(72) Inventors: Qineng XIAO, Dongguan (CN); Dagao ZHENG, Shenzhen (CN); Jun-Chun QIU, Shenzhen (CN); Zhenhong TANG, Shenzhen (CN)

(21) Appl. No.: 19/437,065

(22) Filed: Dec. 30, 2025

(30) Foreign Application Priority Data
Jan. 13, 2025 (CN) 2025200764199

(51) Int. Cl. H05K 7/20; H05K 1/02

(52) U.S. Cl. CPC H05K 7/20263; H05K 1/0203; H05K 7/20254; H05K 7/20272

(57) ABSTRACT

The present disclosure relates to a liquid-cooling device. The liquid-cooling radiator assemblies include a first and a second liquid-cooling radiator assembly. The first liquid-cooling radiator assembly includes a first radiator and a first pump, and the second liquid-cooling radiator assembly includes a second radiator and a second pump. The first and the second heat-generating elements are arranged in groups. The first liquid-cooling head assemblies include multiple first liquid-cooling heads and multiple first liquid-cooling tubes. Each first liquid-cooling head is thermally coupled to a corresponding first heat-generating element, and each first liquid-cooling tube is connected to the first radiator. The second liquid-cooling head assemblies include multiple second liquid-cooling heads and multiple second liquid-cooling tubes. Each second liquid-cooling head is thermally coupled to a corresponding second heat-generating element, and each second liquid-cooling tube is connected to the second radiator.

### BACKGROUND OF THE INVENTION

### TECHNICAL FIELD

The present disclosure relates to a liquid cooling device, and more particularly to a multi-heat source liquid cooling device.

### DESCRIPTION OF RELATED ART

Liquid-cooling devices of the related art commonly deliver coolant to a heat-dissipating module via a pump. After the coolant absorbs heat from a heat-generating source, the heat is released through a cooler, such as a heat sink or a heat exchanger, thereby forming a circulation path. In addition, heat-dissipating modules with a multi-heat source design typically include multiple branch pipelines, each connected to a different heat-generating source, such as a CPU, GPU, or power module, in order to achieve the purpose of cooling multiple heat sources simultaneously.

Moreover, with the trend of miniaturization and thinning of electronic devices and equipment, substrates equipped with heat-generating sources (such as circuit boards or motherboards) need to reduce their footprint while retaining as much space as possible for chips, circuits, or other electronic components. Accordingly, how to configure a liquid-cooling device for dispersed multiple heat sources to effectively dissipate heat from these multiple heat sources is the motivation for the present applicant's research.

In view of the above drawbacks, the inventor proposes this disclosure based on his expert knowledge and elaborate researches in order to solve the problems of related art.

### SUMMARY OF THE INVENTION

One objective of this disclosure is to provide a multi-heat source liquid-cooling device, which is configured for dispersed multiple heat sources so as to effectively dissipate heat, thereby increasing convenience in use.

This disclosure provides a multi-heat source liquid-cooling device including a plurality of liquid-cooling radiator assemblies, a plurality of first heat-generating elements, a plurality of second heat-generating elements, and a plurality of second liquid-cooling head assemblies. The liquid-cooling radiator assemblies include a first liquid-cooling radiator assembly and a second liquid-cooling radiator assembly arranged in parallel. The first liquid-cooling radiator assembly includes a first liquid-cooling radiator and a first pump disposed in the first liquid-cooling radiator. The second liquid-cooling radiator assembly includes a second liquid-cooling radiator and a second pump disposed in the second liquid-cooling radiator. The first heat-generating elements are arranged in a group on one side of the liquid-cooling radiator assemblies. The second heat-generating elements are arranged in a group on one side of the first heat-generating elements. Each of the first liquid-cooling head assemblies includes a first liquid-cooling head and a first liquid-cooling tube. The first liquid-cooling heads are thermally connected to the first heat-generating elements, and the first liquid-cooling tubes are connected to the first liquid-cooling radiator. Each of the second liquid-cooling head assemblies includes a second liquid-cooling head and a second liquid-cooling tube. The second liquid-cooling heads are thermally connected to the second heat-generating elements, and the second liquid-cooling tubes are connected to the second liquid-cooling radiator.

In one embodiment, this disclosure further includes a plurality of third heat-generating elements and a plurality of third liquid-cooling head assemblies. The liquid-cooling radiator assemblies further include a third liquid-cooling radiator assembly arranged in parallel with the second liquid-cooling radiator assembly. The third liquid-cooling radiator assembly includes a third liquid-cooling radiator and a third pump disposed within the third liquid-cooling radiator. The third liquid-cooling head assemblies each include a third liquid-cooling head and a third liquid-cooling tube. The third liquid-cooling heads are thermally connected to the third heat-generating elements, and the third liquid-cooling tubes are connected to the third liquid-cooling radiator.

In one embodiment of this disclosure, the first liquid-cooling head assemblies further include a plurality of first pipe fittings. The first pipe fittings are respectively disposed on the first liquid-cooling tubes and are located between the first liquid-cooling heads and the first liquid-cooling radiator.

In one embodiment of this disclosure, the second liquid-cooling head assemblies further include a plurality of second pipe fittings. The second pipe fittings are respectively disposed on the second liquid-cooling tubes and located between the second liquid-cooling heads and the second liquid-cooling radiator.

In one embodiment of this disclosure, the multi-heat source liquid-cooling device further includes a motherboard. The first heat-generating elements and the second heat-generating elements are disposed on the motherboard.

In one embodiment of this disclosure, the multi-heat source liquid-cooling device further includes a partition plate disposed between the motherboard and the liquid-cooling radiator assemblies.

In one embodiment of this disclosure, the multi-heat source liquid-cooling device further includes a fan assembly disposed on one side of the liquid-cooling radiator assemblies.

In one embodiment of this disclosure, the multi-heat source liquid-cooling device further includes a chassis. The liquid-cooling radiator assemblies, the motherboard, and the fan assembly are disposed within the chassis.

In one embodiment of this disclosure, each of the first liquid-cooling heads includes a first housing, a plurality of first fins disposed within the first housing, and a plurality of first connecting tubes communicating with the interior of the first housing. The first connecting tubes are connected to the first liquid-cooling tubes.

In one embodiment of this disclosure, each of the second heat-generating elements is disposed on a circuit board. The second liquid-cooling head further includes a backplate. The circuit board is clamped and positioned between the backplate and the second liquid-cooling head.

Compared with the related art, the multi-heat source liquid-cooling device of the present disclosure includes liquid-cooling radiator assemblies, which include a first liquid-cooling radiator assembly and a second liquid-cooling radiator assembly arranged in parallel, with the first and second heat-generating elements arranged in groups on one side of the radiator assemblies. Furthermore, a plurality of first and second liquid-cooling head assemblies are respectively disposed corresponding to the first and second heat-generating elements. Accordingly, the configuration of the multi-heat source liquid-cooling device effectively dissipates heat from the dispersed multiple heat sources, thereby enhancing its practical utility and convenience in use.

### BRIEF DESCRIPTION OF THE DRAWINGS

The features of the disclosure believed to be novel are assembly forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a schematic view illustrating an application of the multi-heat source liquid cooling device.

FIGS. 2 and 3 illustrate perspective schematic views from two lateral sides of the multi-heat source liquid cooling device of the present disclosure.

FIG. 4 is a sectional view of the assembly of the multi-heat source liquid-cooling device of the present disclosure.

FIG. 5 is a perspective schematic view of the first liquid cooling head of the present disclosure.

FIG. 6 is a sectional view of the assembly of the first liquid cooling head of the present disclosure.

FIG. 7 is a schematic view illustrating the coupling of the second liquid cooling head and the second heat-generating element of the present disclosure.

FIG. 8 is a perspective exploded view of the second liquid-cooling head and the second heat-generating element of the present disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

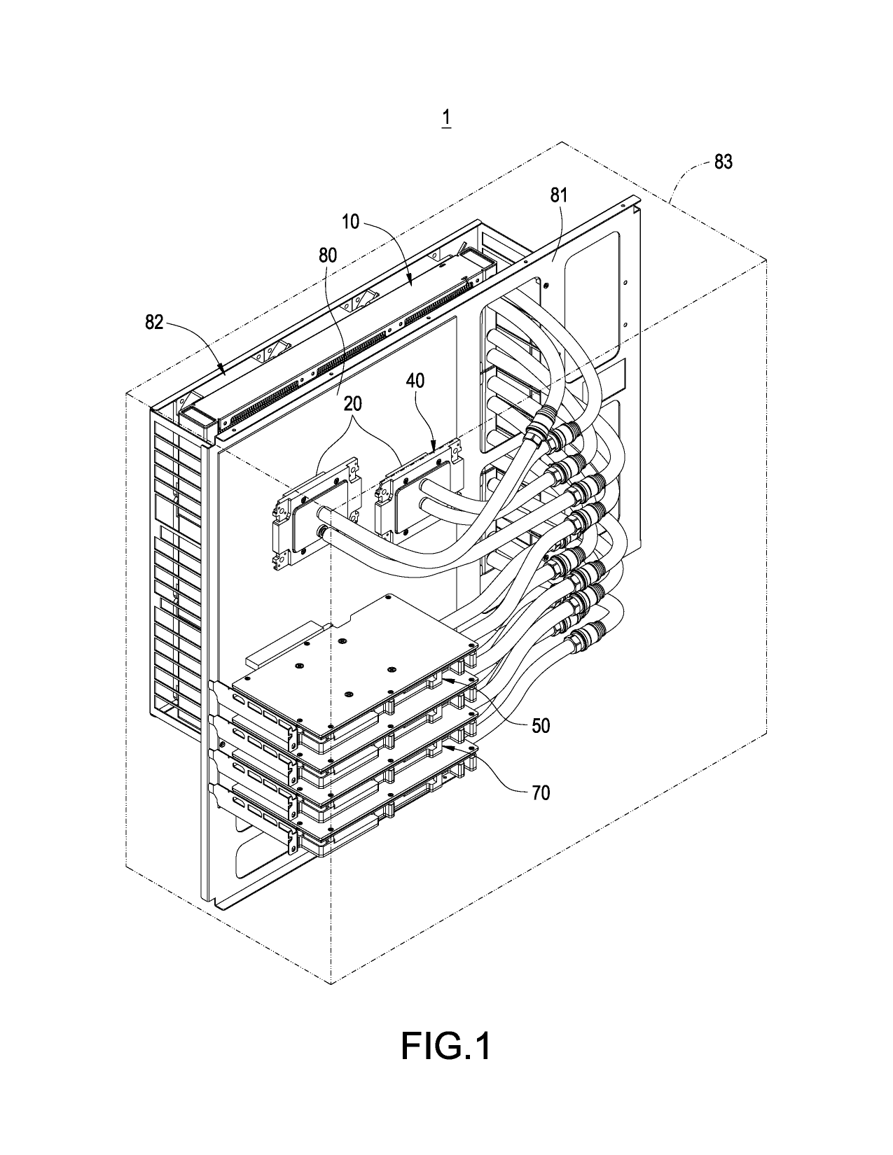

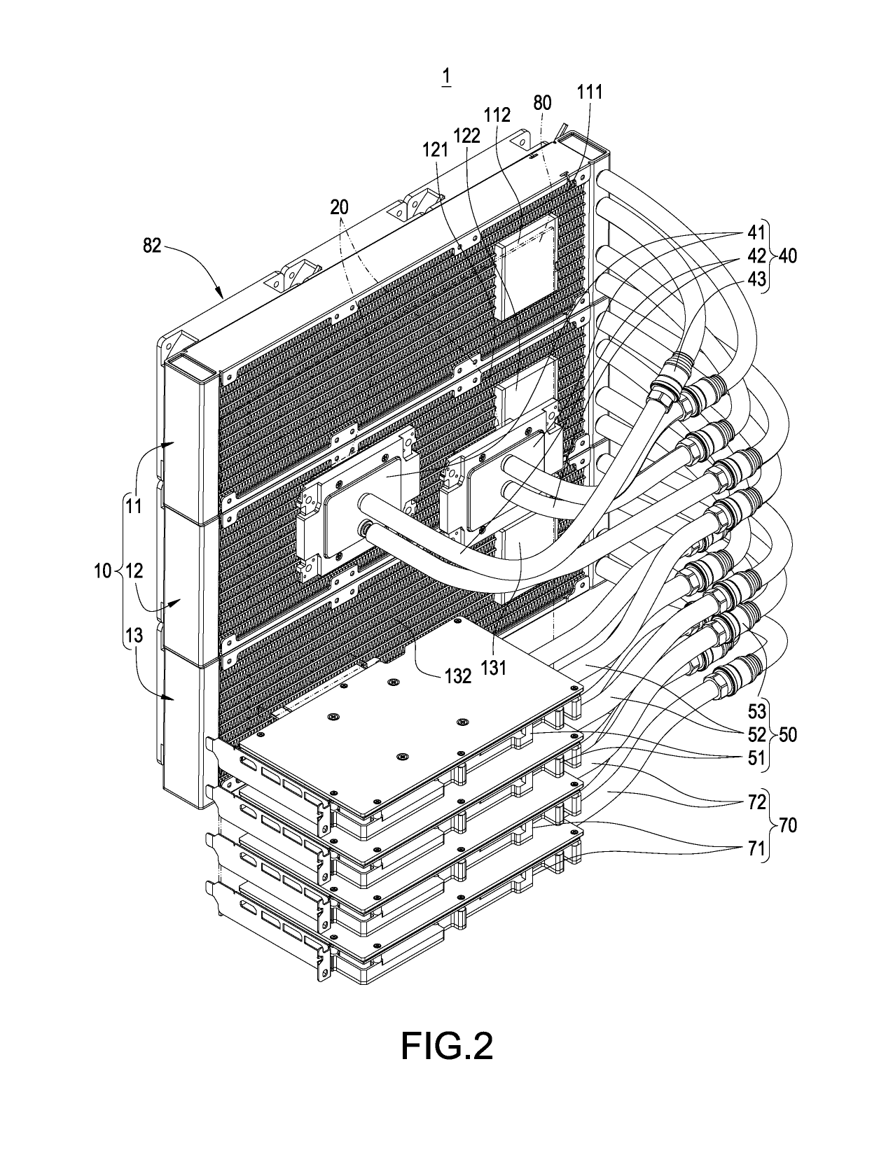

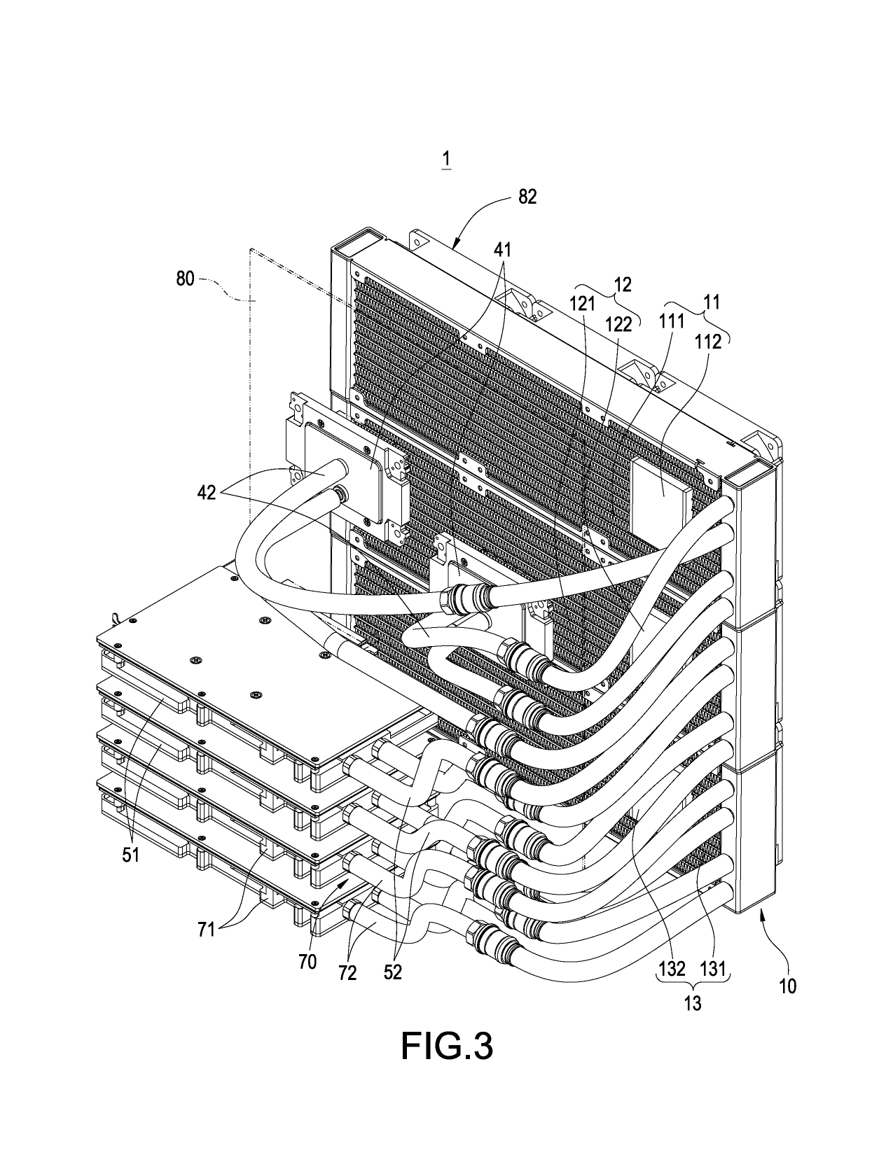

Please refer to FIGS. 1 to 4, which illustrate an application view, perspective views from two lateral directions, and a sectional view of the assembly of the multi-heat source liquid-cooling device of the present disclosure. The present disclosure relates to a multi-heat source liquid-cooling device 1, which includes a plurality of liquid-cooling radiator assemblies 10, a plurality of first heat-generating elements 20, a plurality of second heat-generating elements 30, a plurality of first liquid-cooling head assemblies 40, and a plurality of second liquid-cooling head assemblies 50. The liquid-cooling radiator assemblies 10 include a first liquid-cooling radiator assembly 11 and a second liquid-cooling radiator assembly 12 arranged in parallel. The first liquid-cooling radiator assembly 11 includes a first radiator 111 and a first pump 112 disposed in the first radiator 111. The second liquid-cooling radiator assembly 12 includes a second radiator 121 and a second pump 122 disposed in the second radiator 121. In addition, the first heat-generating elements 20 are arranged in groups on one side of the liquid-cooling radiator assemblies 10, and the second heat-generating elements 30 are arranged in groups on one side of the first heat-generating elements 20.

Furthermore, the first liquid-cooling head assemblies 40 include a plurality of first liquid-cooling heads 41 and a plurality of first liquid-cooling tubes 42. The first liquid-cooling heads 41 are thermally coupled to the first heat-generating elements 20. The first liquid-cooling tubes 42 are connected to the first radiator 111. Additionally, the second liquid-cooling head assemblies 50 include a plurality of second liquid-cooling heads 51 and a plurality of second liquid-cooling tubes 52. The second liquid-cooling heads 51 are thermally coupled to the second heat-generating elements 30. The second liquid-cooling tubes 52 are connected to the second radiator 121.

It should be noted that the first liquid-cooling head assemblies 40 further include a plurality of first pipe fittings 43. The first pipe fittings 43 are respectively disposed on the first liquid-cooling tubes 42 and are located between the corresponding first liquid-cooling heads 41 and the first radiator 111. Additionally, the second liquid-cooling head assemblies 50 further include a plurality of second pipe fittings 53. The second pipe fittings 53 are respectively disposed on the second liquid-cooling tubes 52 and are located between the corresponding second liquid-cooling heads 51 and the second radiator 121.

In the embodiment of the present disclosure, the multi-heat source liquid-cooling device 1 further includes a plurality of third heat-generating elements 60 and a plurality of third liquid-cooling head assemblies 70. The liquid-cooling radiator assemblies 10 include a third liquid-cooling radiator assembly 13 arranged in parallel with the second liquid-cooling radiator assembly 12. The third liquid-cooling radiator assembly 13 includes a third liquid-cooling radiator 131 and a third pump 132 disposed in the third liquid-cooling radiator 131. The third liquid-cooling head assemblies 70 include a plurality of third liquid-cooling heads 71 and a plurality of third liquid-cooling tubes 72. The third liquid-cooling heads 71 are thermally connected to the third heat-generating elements 60, and the third liquid-cooling tubes 72 are connected to the third liquid-cooling radiator 131.

In the present embodiment, the multi-heat source liquid-cooling device 1 further includes a motherboard 80, a partition plate 81, a fan assembly 82, and a chassis 83. The liquid-cooling radiator assemblies 10, the motherboard 80, and the fan assembly 82 are installed in the chassis 83. The motherboard 80 is provided with the first heat-generating elements 20, the second heat-generating elements 30, and the third heat-generating elements 60. The partition plate 81 is disposed between the motherboard 80 and the liquid-cooling radiator assemblies 10. The fan assembly 82 is disposed on one side of the liquid-cooling radiator assemblies 10. Accordingly, the configuration of the multi-heat source liquid-cooling device 1 enables effective heat dissipation for multiple distributed heat sources.

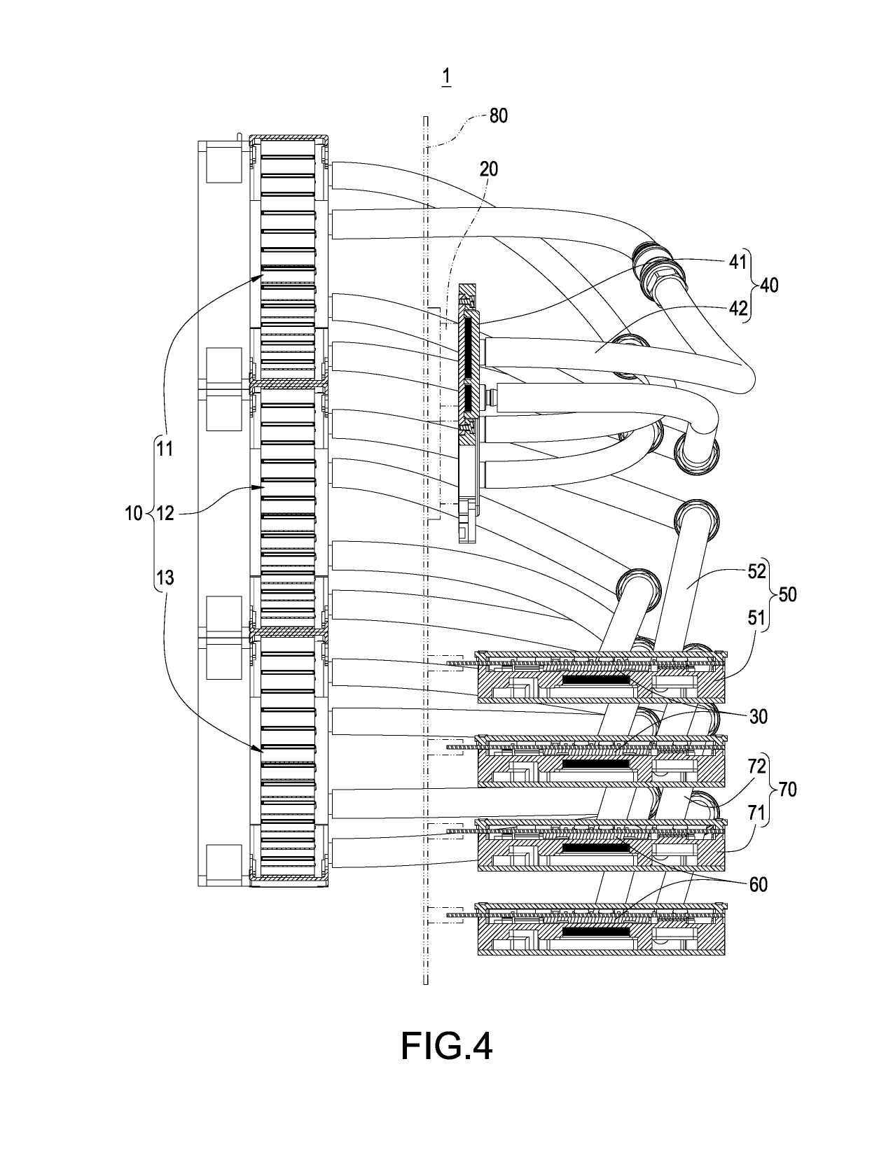

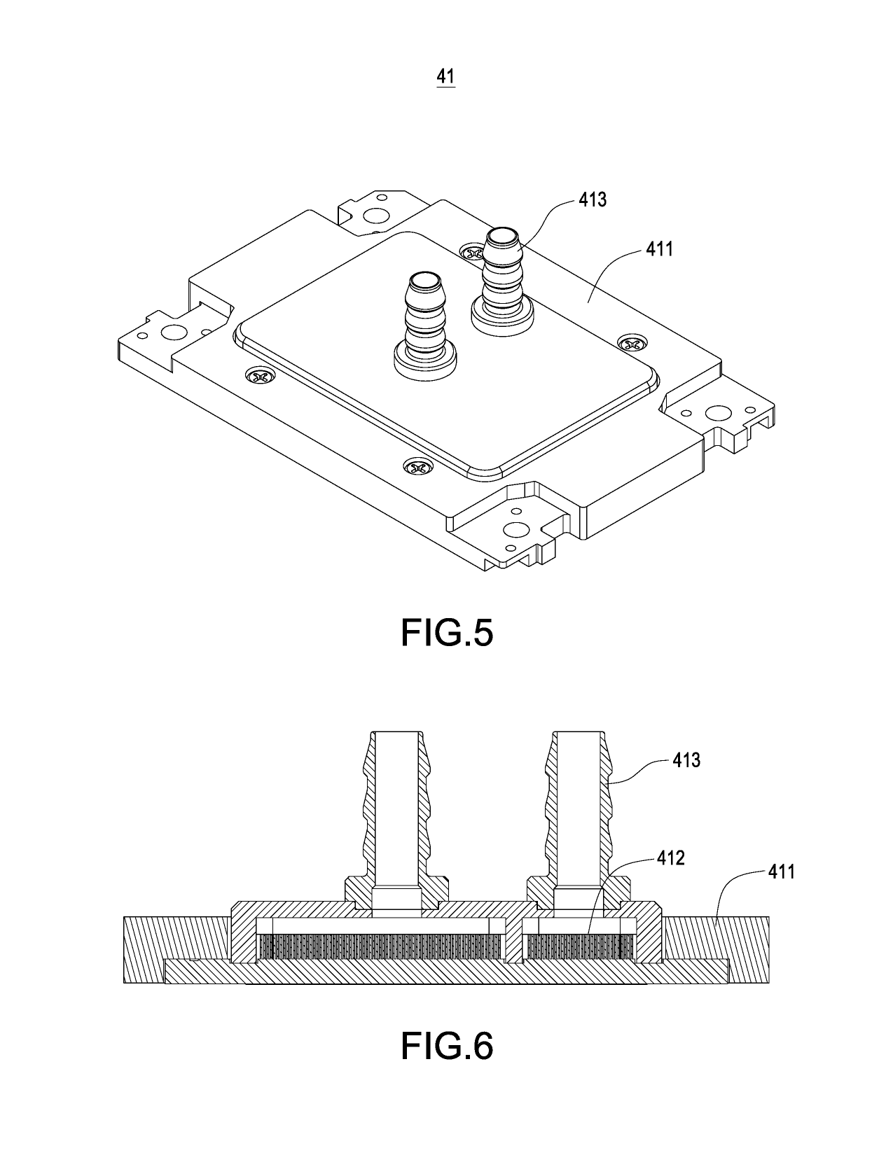

Referring also to FIG. 5 and FIG. 6, which respectively illustrate a perspective view and a sectional view of the assembly of the first liquid-cooling head of the present disclosure, the first liquid-cooling head 41 includes a first housing 411, a plurality of first fins 412 disposed within the first housing 411, and a plurality of first connecting tubes 413 communicating with the interior of the first housing 411. The first connecting tubes 413 are configured to be connected to the aforementioned first liquid-cooling tubes 42.

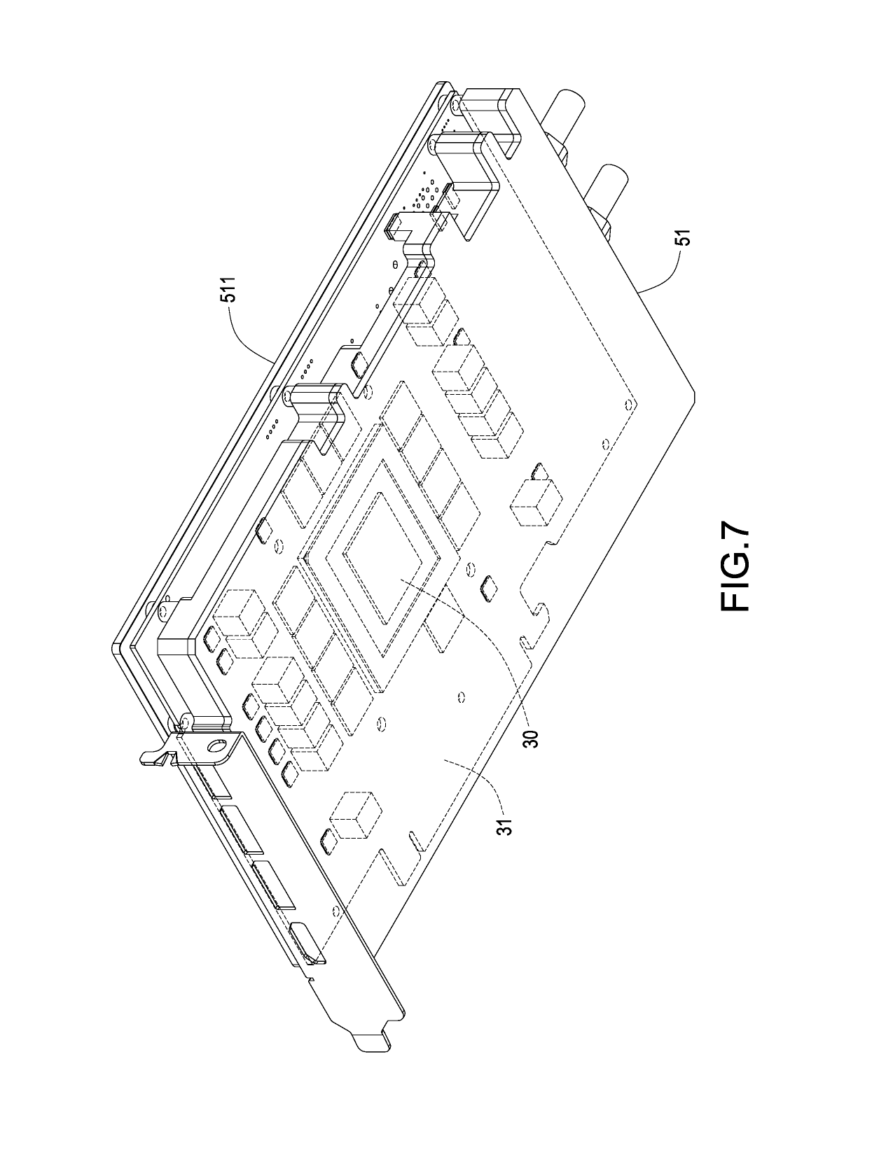

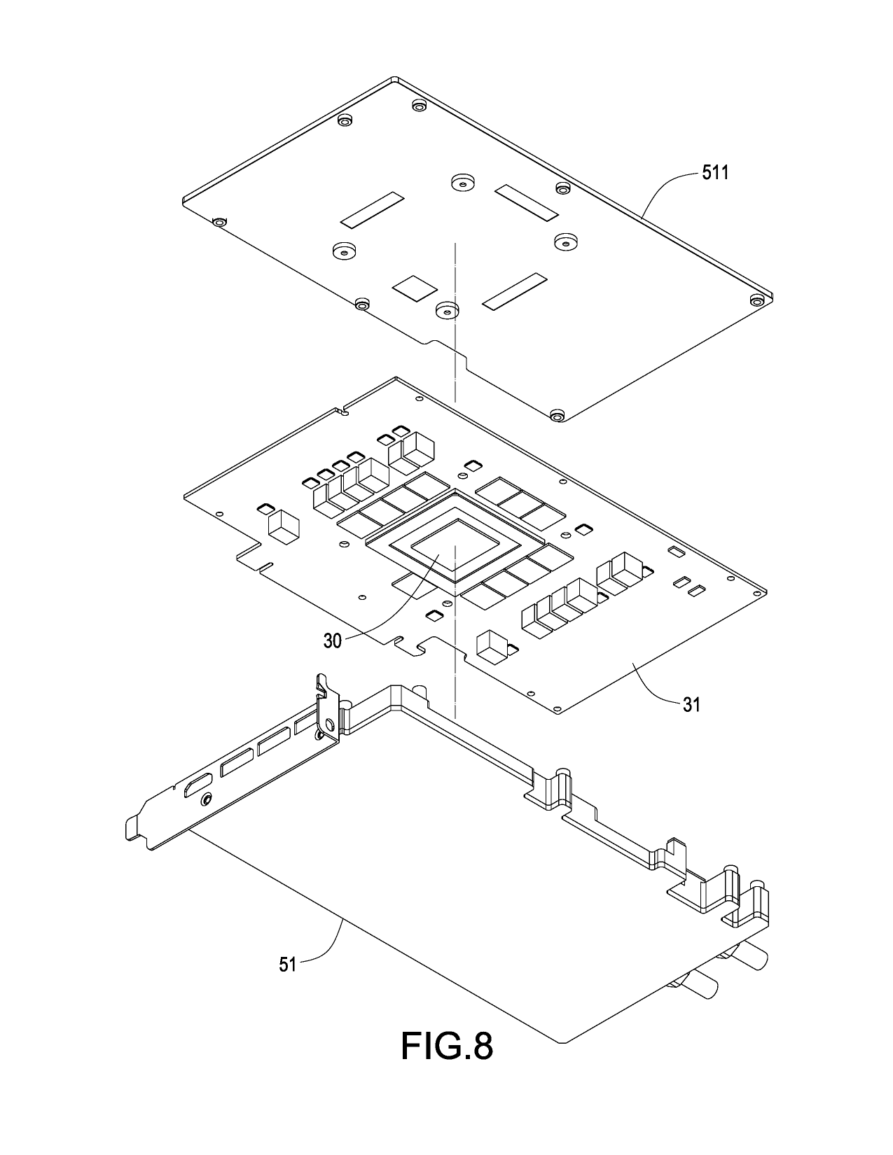

Referring further to FIG. 7 and FIG. 8, which respectively illustrate a schematic view of the coupling of the second liquid-cooling head and the second heat-generating element, and an exploded perspective view thereof, the internal structure of the second liquid-cooling head 51 is substantially the same as that of the first liquid-cooling head 41 and need not be described in detail herein. In this embodiment, the second heat-generating element 30 is disposed on a circuit board 31. The second liquid-cooling head 51 further includes a backplate 511. The circuit board 31 is clamped and positioned between the backplate 511 and the second liquid-cooling head 51, thereby allowing the second liquid-cooling head 51 to dissipate heat from the second heat-generating element 30.

While this disclosure has been described by means of specific embodiments, numerous modifications and variations may be made thereto by those skilled in the art without departing from the scope and spirit of this disclosure assembly forth in the claims.

What is claimed is:

1. A liquid-cooling device, comprising:
a plurality of liquid-cooling radiator assemblies, including a first liquid-cooling radiator assembly and a second liquid-cooling radiator assembly arranged in parallel, wherein the first liquid-cooling radiator assembly comprises a first liquid-cooling radiator and a first pump disposed in the first liquid-cooling radiator, and the second liquid-cooling radiator assembly comprises a second liquid-cooling radiator and a second pump disposed in the second liquid-cooling radiator;
a plurality of first heat-generating elements, arranged in a group on one side of the liquid-cooling radiator assemblies;
a plurality of second heat-generating elements, arranged in a group on one side of the first heat-generating elements;
a plurality of first liquid-cooling head assemblies, each comprising a first liquid-cooling head and a first liquid-cooling tube, the first liquid-cooling heads being thermally connected to the first heat-generating elements, and the first liquid-cooling tubes being connected to the first liquid-cooling radiator; and
a plurality of second liquid-cooling head assemblies, each comprising a second liquid-cooling head and a second liquid-cooling tube, the second liquid-cooling heads being thermally connected to the second heat-generating elements, and the second liquid-cooling tubes being connected to the second liquid-cooling radiator.

2. The liquid-cooling device according to claim 1, further comprising a plurality of third heat-generating elements and a plurality of third liquid-cooling head assemblies, wherein the liquid-cooling radiator assemblies further comprises a third liquid-cooling radiator assembly arranged in parallel with the second liquid-cooling radiator assembly, the third liquid-cooling radiator assembly comprising a third liquid-cooling radiator and a third pump disposed within the third liquid-cooling radiator, and wherein the third liquid-cooling head assemblies each comprise a third liquid-cooling head and a third liquid-cooling tube, the third liquid-cooling heads being thermally connected to the third heat-generating elements, and the third liquid-cooling tubes being connected to the third liquid-cooling radiator.

3. The liquid-cooling device according to claim 1, wherein the first liquid-cooling head assemblies further comprise a plurality of first pipe fittings, the first pipe fittings being respectively disposed on the first liquid-cooling tubes and located between the first liquid-cooling heads and the first liquid-cooling radiator.

4. The liquid-cooling device according to claim 1, wherein the second liquid-cooling head assemblies further comprise a plurality of second pipe fittings, the second pipe fittings being respectively disposed on the second liquid-cooling tubes and located between the second liquid-cooling heads and the second liquid-cooling radiator.

5. The liquid-cooling device according to claim 1, further comprising a motherboard, wherein the first heat-generating elements and the second heat-generating elements are disposed on the motherboard.

6. The liquid-cooling device according to claim 5, further comprising a partition plate disposed between the motherboard and the liquid-cooling radiator assemblies.

7. The liquid-cooling device according to claim 5, further comprising a fan assembly disposed on one side of the liquid-cooling radiator assemblies.

8. The liquid-cooling device according to claim 7, further comprising a chassis, wherein the liquid-cooling radiator assemblies, the motherboard, and the fan assembly are disposed within the chassis.

9. The liquid-cooling device according to claim 1, wherein each of the first liquid-cooling heads comprises a first housing, a plurality of first fins disposed within the first housing, and a plurality of first connecting tubes communicating with an interior of the first housing, the first connecting tubes being connected to the first liquid-cooling tubes.

10. The liquid-cooling device according to claim 1, wherein each of the second heat-generating elements is disposed on a circuit board, and the second liquid-cooling head further comprises a backplate, the circuit board being clamped and positioned between the backplate and the second liquid-cooling head.
